(19) United States
(12) Patent Application Publication
(10) Pub. No.: US 2026/0176758 A1
(43) Pub. Date: Jun. 25, 2026

(54) METHOD TO FILL A GAP

(71) Applicant: ASM IP Holding B.V., Almere (NL)

(72) Inventors: René Henricus Jozef Vervuurt, Leuven (BE); Viljami Pore, Helsinki (FI)

(21) Appl. No.: 19/422,749

(22) Filed: Dec. 17, 2025

Related U.S. Application Data
(60) Provisional application No. 63/736,802, filed on Dec. 20, 2024.

(51) Int. Cl. C23C 16/455; C23C 16/34; C23C 16/40

(52) U.S. Cl. CPC C23C 16/45536; C23C 16/345; C23C 16/401; C23C 16/45553

(57) ABSTRACT

A method for filling a gap in a substrate is disclosed. The method includes providing a substrate with a gap in a reaction chamber, forming first active species from a first reactant to create an inhibition layer near the top of the gap, and performing one or more deposition cycles to deposit material into the gap. Each deposition cycle involves introducing a second reactant to form a chemisorbed layer and generating a second active species from a third reactant using pulsed plasma power, which reacts with the chemisorbed layer to form a deposited layer. The inhibition layer partially inhibits deposition at the top of the gap. The deposited material comprises silicon nitride, which is subsequently converted to silicon oxide by providing a fourth reactant containing hydrogen and oxygen. This conversion results in volume expansion and improved gap filling.

### CROSS-REFERENCE TO RELATED APPLICATIONS

This application claims priority to U.S. Provisional Patent Application Ser. No. 63/736,802 filed Dec. 20, 2024 titled METHOD TO FILL A GAP, the disclosure of which is hereby incorporated by reference in its entirety.

### FIELD OF INVENTION

The present disclosure relates generally to filling a gap in a substrate. The present disclosure more specifically relates to filling a gap with silicon oxide (SiO₂).

### BACKGROUND OF THE DISCLOSURE

Semiconductor fabrication processes for forming semiconductor device structures, such as, for example, transistors, memory elements, and integrated circuits, are wide ranging and may include deposition processes. The deposition process may be filling a gap in a substrate.

The structures on the substrate may comprise a gap, which may be a hollow feature accessible via an opening in the surface of the substrate. The deposition processes of the silicon oxide layer on the substrate may become challenging if the deposited layer needs to be deposited inside the hollow feature as well via the opening to fill the gap.

Accordingly, there is a need for a deposition process for silicon oxide that is able to fill the gap in the substrate.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In at least one embodiment of the invention, a method for filling a gap is provided. The method may comprise: providing a substrate with a gap in a reaction chamber; forming first active species from a first reactant for forming an inhibition layer in a vicinity of a top of the gap. The method may further comprise performing one or more deposition cycles to deposit a material into the gap, wherein each deposition cycle comprises: introducing a second reactant to the reaction chamber, wherein the second reactant reacts with the surface of the substrate to form a chemisorbed layer in the gap; and forming a second active species from a third reactant that reacts with the chemisorbed layer to form a deposited layer, wherein the second active species is formed providing pulsed plasma power to an electrode for a plasma power period to form a plasma within the reaction chamber, wherein the reaction of the second reactant in the vicinity of the top of the gap is at least partially inhibited by the inhibition layer, and the deposited material comprises silicon nitride. A fourth reactant comprising hydrogen and oxygen may be provided to convert the silicon nitride into silicon oxide.

In at least one embodiment of the invention the fourth reactant comprises one or more molecules selected from water and hydrogen peroxide.

In at least an embodiment of the invention providing the fourth reactant to convert the silicon nitride to silicon oxide gives between 20 to 70% volume expansion of the deposited material.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a non-limiting exemplary process flow, demonstrating a method for filing a gap with silicon oxide on a substrate.

FIGS. 2a and 2b illustrate a structure formula of a second reactant which can be used in the method of FIG. 1.

FIG. 3 depicts a cross-section of a gap filled using the method of FIG. 1 and the second reactant from FIG. 2a.

The illustration presented herein is not meant to be actual views of any particular material, structure, or device, but are merely idealized representations that are used to describe embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials that may be used, or upon which, a device, a circuit, or a layer may be formed.

As used herein, the term “cyclical chemical vapor deposition” may refer to any process wherein a substrate is sequentially exposed to one or more volatile precursors, which react and/or decompose on a substrate to produce a desired deposition.

As used herein, the term plasma may refer to a state of matter characterized by the presence of a significant portion of charged particles in any combination of ions or electrons. The plasma may be used to generate active species from the reactants.

As used herein, the term reactant may refer to a gas comprising silicon, phosphorus hydrogen, oxygen, or nitrogen or any mixture thereof.

As used herein, the term “atomic layer deposition” (ALD) may refer to a vapor deposition process in which deposition cycles, preferably a plurality of consecutive deposition cycles, are conducted in a reaction chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “layer” and “thin layer” may refer to any continuous or non-continuous structures and material formed by the methods disclosed herein. For example, “layer” and “thin layer” could include 2D materials, nanolaminates, nanorods, nanotubes, or nanoparticles, or even partial or full molecular layers, or partial or full atomic layers or clusters of atoms and/or molecules. “Layer” and “thin layer” may comprise material or a layer with pinholes, but still be at least partially continuous.

A number of example materials are given throughout the embodiments of the current disclosure, it should be noted that the chemical formulas given for each of the materials should not be construed as limiting and that the non-limiting example materials given should not be limited by a given example stoichiometry.

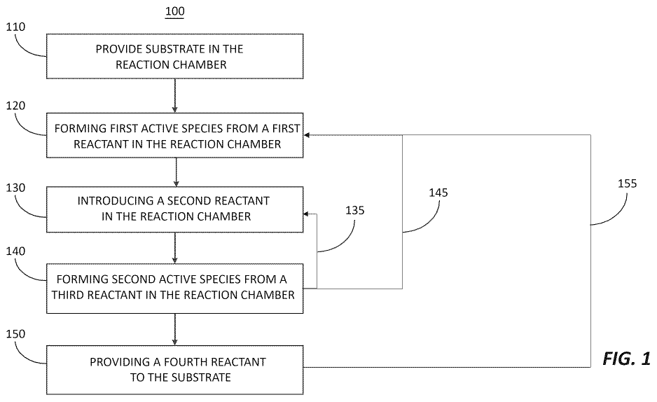

FIG. 1 illustrates a method 100 for filling a gap in a substrate with silicon oxide on a substrate. In at least one embodiment of the invention, the method may comprise: providing a substrate with a gap in a reaction chamber 110 and forming first active species from a first reactant for forming an inhibition layer in a vicinity of a top of the gap 120. The inhibition layer in the top of the gap may substantially block any subsequent deposition steps.

The method 100 may further comprises performing one or more deposition cycles to deposit a material into the gap, wherein each deposition cycle comprises: introducing a second reactant to the reaction chamber 130, wherein the second reactant reacts with the surface of the substrate to form a chemisorbed layer in the gap on the location where there is no inhibition layer and forming a second active species from a third reactant 140 that reacts with the chemisorbed layer to form a deposited layer. The second active species is formed providing pulsed plasma power to an electrode for a plasma power period to form a plasma within the reaction chamber. The reaction of the second reactant in the vicinity of the top of the gap is at least partially inhibited by the inhibition layer, and the deposited material comprises silicon nitride doped with phosphorus.

In some embodiments, the deposition cycle may be repeated 135 until sufficient material is provided in the gap or the inhibition layer becomes inactive. The inhibition layer may be renewed by step 145 if it becomes inactive. The inhibition layer may be renewed every 1 to 33 deposition cycles for example. Thereafter the method may proceed with the deposition cycle 135. Again, these steps may be repeated 145.

A fourth reactant comprising hydrogen and oxygen is provided 150 to convert the silicon nitride into silicon oxide. The fourth reactant comprises one or more molecules selected from water and hydrogen peroxide. The fourth reactant converts the silicon nitride to silicon oxide giving between 20 to 70% volume expansion of the deposited material which helps in filling the gap. The conversion makes the material flowable so that it flows to the bottom of the gap which also helps in filling the gap.

Providing the fourth reactant may be repeated 1 to 3 times 155. The fourth reactant may be provided in a separate tool or reaction chamber, for example, in a vertical furnace and the method may comprise transferring the substrate from the reaction chamber to the vertical furnace. The fourth reactant may be provided by providing oxygen and hydrogen and ignite it to form water. The substrate may be heated to 100 to 500° C. when the fourth reactant is provided. The water may be provided during a steam anneal for the conversion of silicon nitrite into silicon oxide.

In at least one embodiment of the invention the substrate may comprise a gap, which is a hollow feature accessible via an opening in the surface of the substrate.

In at least an embodiment the plasma may be a continuous wave plasma. A continuous wave plasma may have the right properties to activate the reactant.

In at least an embodiment the deposited material comprises phosphorus. The phosphorus may enable the conversion of SiON:P to SiO:P. With the phosphorus (P) the conversion will occur at temperatures between 100-500° C. if the quality of the SiN is good. A 5% phosphorus content may be the minimum required for the deposited SiON:P. In some embodiments, the conversion may worked by converting the phosphorous to phosphoric acid during H₂O exposure. The phosphoric acid then converts SiN to SiO releasing NH₃.

In at least an embodiment the method comprises introducing a fifth reactant comprising phosphorus.

In at least an embodiment the second reactant may comprise phosphorus which may end up in the deposited material. The second reactant may comprise phosphite or phosphate.

In at least an embodiment the second reactant may comprise a methyl group. The second reactant may comprise a methylsilyl group. The second reactant may comprise a trimethylsilyl group. The second reactant may comprise three trimethylsilyl groups.

In at least an embodiment the second reactant comprises oxygen or silicon.

In at least an embodiment the second reactant comprises Tris(trimethylsilyl)phosphite.

In at least an embodiment the second reactant comprises Tris(trimethylsilyl)phosphate.

In at least an embodiment the deposited material comprises oxygen.

In at least an embodiment the third reactant comprises nitrogen. The nitrogen may be molecular nitrogen (N₂).

In at least an embodiment the first reactant may comprise nitrogen. The first reactant may be one or more selected from the group comprising nitrogen fluorine (NF₃), ammonia (NH₃), diazine (N₂H₂), hydrogen (H₂) or nitrogen (N₂). A good inhibition layer may be made with nitrogen fluorine (NF₃), ammonia (NH₃), diazine (N₂H₂), hydrogen (H₂) or nitrogen (N₂)

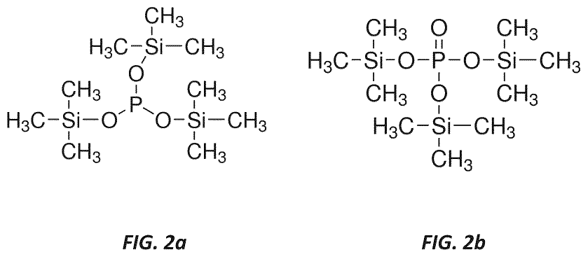

FIGS. 2a and 2b illustrate a structure formula of a second reactant which can be used in the method of FIG. 1. FIG. 2a discloses Tris(trimethylsilyl)phosphite. FIG. 2b discloses Tris(trimethylsilyl)phosphate.

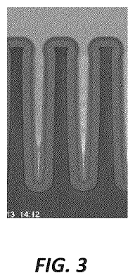

FIG. 3 discloses a picture of a fill of a gap using the method of FIG. 1 and the second reactant from FIG. 2a. The picture shows that the gap is very well filled over its length using the method of the disclosure.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for filling a gap, the method comprising the steps of:
providing a substrate with a gap in a reaction chamber;
forming first active species from a first reactant for forming an inhibition layer in a vicinity of a top of the gap; and
performing one or more deposition cycles to deposit a material into the gap, wherein each deposition cycle comprises:
introducing a second reactant to the reaction chamber, wherein the second reactant reacts with the surface of the substrate to form a chemisorbed layer in the gap; and
forming a second active species from a third reactant that reacts with the chemisorbed layer to form a deposited layer,
wherein the second active species is formed providing pulsed plasma power to an electrode for a plasma power period to form a plasma within the reaction chamber,
wherein the reaction of the second reactant in the vicinity of the top of the gap is at least partially inhibited by the inhibition layer, and the deposited material comprises silicon nitride, wherein a fourth reactant comprising hydrogen and oxygen is provided to convert the silicon nitride into silicon oxide.

2. The method according to claim 1, wherein the fourth reactant comprises one or more molecules selected from water and hydrogen peroxide.

3. The method according to claim 1, wherein providing the fourth reactant to convert the silicon nitride to silicon oxide gives between 20 to 70% volume expansion of the deposited material.

4. The method according to claim 1, wherein the inhibition layer is formed every 1 to 33 deposition cycles.

5. The method according to claim 1, wherein providing the fourth reactant is repeated 1 to 3 times.

6. The method according to claim 1, wherein the fourth reactant is provided in a vertical furnace and the method comprises transferring the substrate from the reaction chamber to the vertical furnace.

7. The method according to claim 1, wherein the fourth reactant is provided by providing oxygen and hydrogen and ignite it to form water.

8. The method according to claim 1, wherein the substrate is heated to 100 to 500° C. and water is provided during a steam anneal for the conversion of silicon nitrite into silicon oxide.

9. The method according to claim 1, wherein the second reactant comprises phosphorus.

10. The method according to claim 9, wherein the method comprises introducing a fifth reactant comprising phosphorus.

11. The method according to claim 9, wherein the second reactant comprises a methyl group.

12. The method according to claim 11, wherein the second reactant comprises a methylsilyl group.

13. The method according to claim 12, wherein the second reactant comprises at least one trimethylsilyl group.

14. The method according to claim 9, wherein the second reactant comprises oxygen.

15. The method according to claim 9, wherein the second reactant comprises silicon.

16. The method according to claim 9, wherein the second reactant comprises Tris(trimethylsilyl)phosphite.

17. The method according to claim 9, wherein the second reactant comprises Tris(trimethylsilyl)phosphate.

18. The method according to claim 1, wherein the deposited material comprises oxygen.

19. The method according to claim 1, wherein the third reactant comprises nitrogen.

20. The method according to claim 1, wherein the first reactant comprises nitrogen.

21. The method according to claim 1, wherein the first reactant is one or more selected from the group comprising nitrogen fluorine (NF₃), ammonia (NH₃), diazine (N₂H₂), hydrogen (H₂) or nitrogen (N₂).
